(19) United States
(12) Patent Application Publication
(10) Pub. No.: US 2017/0124026 A1
(43) Pub. Date: May 4, 2017

(54) METHOD FOR SOLVING HIGH-DIMENSIONAL NONLINEAR FILTERING PROBLEM

(71) Applicant: SHING-TUNG YAU, CAMBRIDGE, MA (US)

(72) Inventors: MEI-HENG YUEH, HSINCHU CITY 300 (TW); WEN-WEI LIN, TAIPEI CITY 112 (TW); SHING-TUNG YAU, CAMBRIDGE, MA (US)

(21) Appl. No.: 14/924,847

(22) Filed: Oct. 28, 2015

(51) Int. Cl. G06F 17/11; H03H 17/02

(52) U.S. Cl. CPC G06F 17/11; H03H 17/0261

(57) ABSTRACT

A method for solving high-dimensional nonlinear filtering problems is revealed. The method uses a fast computational module to solve an equation and get approximate numerical solutions of a signal-observation model. The equation-solving process of the fast computational module is speeded up by a transformation module and the computational stability is further improved. D-dimensional nonlinear filtering problems are solved and approximate numerical solutions are obtained based on Yau-Yau filtering theory. A Quasi-Implicit Euler Method (QIEM) is applied to solve the Kolmogorov equations and estimate approximate numerical solutions of the signal-observation model. Moreover, QIEM is more efficient and the numerical solutions are more stable by Fast Fourier transformation (FFT) acceleration.

### BACKGROUND OF THE INVENTION

1. Field of the invention

The present invention relates to a method for solving high-dimensional nonlinear filtering problems, especially to a method for solving high-dimensional nonlinear filtering problems that solves D-dimensional nonlinear filtering problems and gets approximate numerical solutions of a signal-observation model based on Yau-Yau filtering theory. A Quasi-Implicit Euler Method (QIEM) is applied to solve the Kolmogorov equations and estimate approximate states of a given signal-observation model. By Fast Fourier transformation (FFT) acceleration, QIEM is more efficient and the numerical solutions are more stable.

2. Description of Related Art

The nonlinear filtering problem has a variety of applications in military, engineering and commercial industries. The core issue of the nonlinear filtering problem is to solve the Duncan-Mortensen-Zakai (DMZ) equation in real time. Yau and Yau have proved that the real-time solution of the DMZ equation can be reduced to an off-time solution of the Kolmogorov equation. Based on the work of Yau and Yau, Liu et al. proposed as numerical method to solve the nonlinear filtering problem by explicit finite difference schemes (Existence and uniqueness and decay estimates for the time dependent parabolic equation with application to Duncan-Mortensen-Zakai equation, Asian Journal of Mathematics, 2:1079-1149, 1998). In order to improve the stability of the algorithm proposed by Liu, an efficient and reliable quasi-implicit numerical scheme is proposed for solving the Kolmogorov equations and estimate approximate states of a given signal-observation model.

### SUMMARY OF THE INVENTION

Therefore it is a primary object of the present invention to provide a method for solving high-dimensional nonlinear filtering problems by which high-dimensional nonlinear filtering problems are solve and approximate numerical solutions of a signal-observation model are obtained based on Yau-Yau filtering theory. A Quasi-Implicit Euler Method (QIEM) is applied to solve Kolmogorov equations and estimate approximate numerical solutions of the signal-observation model. Moreover, stability of the numerical solutions is ensured by fast Fourier transformation (FFT) applied in the QIEM.

In order to achieve the above object, a method for solving high-dimensional nonlinear filtering problems of the present invention solves an equation and obtains approximate numerical solutions of a signal-observation model by using a fast computational module. Moreover, the equation-solving process of the fast computational module is speeded up by a transformation module in order to improve the computational stability.

In the fast computational module, a Quasi-Implicit Euler Method (QIEM) is applied to solve Kolmogorov equations and estimate approximate numerical solutions of the given signal-observation model.

In the method mentioned above, the Quasi-Implicit Euler Method(QIEM) is iteratively formulated by:

$$[ {I}_{{N}^{D}} - \frac{Δ t}{2 {( Δ s )}^{2}} {L}_{N}^{( D )} ] {u}_{n + 1} = [ {I}_{{N}^{D}} + Δ t ( \frac{1}{2 Δ s} {K}_{N}^{( D )} + {Q}_{N}^{( D )} ) ] {u}_{N} ;$$

$$wherein {L}_{N}^{( D )} = {\sum }_{d = 1}^{D} [ {I}_{{N}^{D - d}} ⊗ {L}_{N} ⊗ {I}_{{N}^{d - 1}} ] , \\ {K}_{N}^{( D )} = {\sum }_{d = 1}^{D} {P}_{d} [ {I}_{{N}^{D - d}} ⊗ {K}_{N} ⊗ {I}_{{N}^{d - 1}} ] ;$$

wherein I_{N} is the identity matrix of size N and P_{d}=diag{p_{d}(sⱼ)}ⱼ₌₁^{N}^{^{D}}, Q=diag{q(sⱼ)}ⱼ₌₁^{N}^{^{D}},
wherein the matrices L_{N} and K_{N} are defined by

$${L}_{N} = [ \begin{matrix}- 2 & 1 & & \\ 1 & - 2 & … & \\ & … & … & 1 \\ & & 1 & - 2\end{matrix} ] , {K}_{N} = [ \begin{matrix}0 & 1 & & \\ - 1 & 0 & … & \\ & … & … & 1 \\ & & - 1 & 0\end{matrix} ]$$

Thereby the method of the present invention solves D-dimensional nonlinear filtering problems and gets approximate numerical solutions of the signal-observation model based on Yau-Yau filtering theory. The approximate numerical solutions of the signal-observation model are obtained by applying Quasi-Implicit Euler Method (QIEM) to solve the Kolmogorov equations. The QIEM is more efficient by fast Fourier transformation (FFT) acceleration. Thus stability of the numerical solutions is ensured and computational cost is significantly saved. Moreover, the numerical solution of the Kolmogorov equations in each iteration is nonnegative. The probability density functions are preserved in the iterative process. The results prove that the present method has high efficiency and great potential.

### DETAILED DESCRIPTION OF THE PREFFERED EMBODIMENT

In order to learn features and functions of the present invention, please refer to the following embodiments with details.

A method for solving high-dimensional nonlinear filtering problems of the present invention solves an equation and gets approximate numerical solutions of a signal-observation model by using a fast computational module. A transformation module is used to accelerate the equation-solving process of the fast computational module for improving the computational stability. In the fast computational module, a Quasi-Implicit Euler Method (QIEM) is applied to solve the Kolmogorov equations and estimate approximate numerical solutions of the signal-observation model.

The nonlinear filtering problem considered here is to determine approximate states for a given observation history of the following signal-observation model:

$$\{ \begin{matrix}dX ( t ) = f ( X ( t ) ) dt + dv ( t ) \\ dY ( t ) = h ( X ( t ) ) dt + dw ( t )\end{matrix} \qquad ( 1 )$$

wherein X(0)=X₀, Y(0)=0,
and X(t)=(xₗ(t), . . . , x_{D}(t))^{T} ∈ R^{D}, Y(t)=(y₁(t), . . . , y_{M}(t))^{T} ∈ R^{M} are the state and the measurement/observation vectors at time t, respectively.
ƒ(X)=(ƒ₁(X), . . . , ƒ_{D}(X))^{T}, h(X)=(h₁(X), . . . , h_{M}(X))^{T} are given vector-valued functions, ν ∈ R^{D} and w ∈ R^{M} are mutually independent standard Brownian processes. From the main results of Yau and Yau, the sate vector x(t) can be estimated from the observation vectors {y(s)|s ∈ [0,t]} by solving the Kolmogorov equations. Specifically, suppose that a set of observations {y(τ₀), . . . , y(τ_{N}, )} is measured. For each time period [τₖ₋₁, τₖ], k=1, . . . , Nₜ, the Kolmogorov equations of the from are solved,

$$\begin{matrix}\{ \begin{matrix}\frac{\partial {\tilde{u}}_{k}}{\partial t} ( t , s ) = \frac{1}{2} Δ {\tilde{u}}_{k} ( t , s ) + {\sum }_{d = 1}^{D} Pd ( s ) \frac{\partial {\tilde{u}}_{k}}{\partial {s}_{d}} ( t , s ) + q ( s ) {\tilde{u}}_{k} ( t , s ) , t ∈ [ {τ}_{k - 1} , {τ}_{k} ] , \\ {\tilde{u}}_{k} ( {τ}_{k - 1} , s ) = exp \{ {\sum }_{j = 1}^{M} [ {y}_{j} ( {τ}_{k - 1} ) - {y}_{j} ( {τ}_{k - 2} ) ] {h}_{j} ( s ) \} {\tilde{u}}_{k - 1} ( {τ}_{k - 1} , s ) , \\ {\tilde{u}}_{1} ( 0 , s ) = {σ}_{0} ( s ) exp \{ {\sum }_{j = 1}^{M} {y}_{j} ( {τ}_{0} ) {h}_{j} ( s ) \} ,\end{matrix} & ( 2 ) \\ \begin{matrix} for k = 2 , … , {N}_{τ} and τ = 0 , wherein Δ = {\sum }_{i = 1}^{D} \frac{{\partial }^{2}}{\partial {s}_{i}^{2}} , & \end{matrix} & \\ {p}_{d} ( s ) = - {f}_{d} ( s ) , d = 1 , … , D , & ( 3 ) \\ and q ( s ) = - [ {\sum }_{d = 1}^{D} \frac{\partial {f}_{d}}{\partial {s}_{d}} ( s ) + \frac{1}{2} {\sum }_{j = 1}^{M} {h}_{j}^{2} ( s ) ] , & ( 4 )\end{matrix}$$

for t ∈[τₖ₋₁, τₖ], k=2, . . . , N, the expectation of ũₖ(t,s) is computed with respect to s_{d}over R^{D} by

$${\hat{x}}_{d} ( t ) = {\int }_{{R}^{D}}^{ } {s}_{d} {\tilde{u} }_{k} ( t , s ) d s , \qquad ( 5 )$$

for d=1, . . . , D. Then the state vector X(t) can be estimated by \hat{X}(t)=(\hat{x}₁(t), . . . , \hat{x}_{D}(t))^{T}.

In order to solve the nonlinear filtering problem (1), the states and observations {Xₖ, Yₖ}ₖ₌₀^{N}^{ᵣ} by using Euler forward difference method with Gaussian noise are first generated. Based on the Yau-Yau method, an implicit Euler method (IEM) for solving the Kolmogorov equation (2) which is stable and reliable, but costly is first proposed. Furthermore, the quasi-implicit Euler method (QIEM) is developed for solving the Kolmogorov equation (2) which is also stable and reliable, but much more efficient because the fast Fourier transformation (FFT) can be applied in the QIEM.

Given a terminal time Γ, a set of states and observations {Xₖ, Yₖ}ₖ₌₀^{N}^{ᵣ} are generated by Euler forward difference method. A time interval [0, Γ] is partitioned uniformly as

P_{[0, Γ]}={0=τ₀<τ₁< . . . <τ_{N}, =Γ}, (6)

wherein τₖ−τₖ₋₁=Δτ, k=1, 2, . . . , Nᵣ. With the Euler forward discretization, the signal observation model in (1) an be stimulated by

$$\{ \begin{matrix}{X}_{k + 1} = {X}_{k} + f ( {X}_{k} ) Δτ + v \sqrt{Δτ} , \\ {Y}_{k + 1} = {Y}_{k} + h ( {X}_{k} ) Δτ + w \sqrt{Δτ} ,\end{matrix}$$

wherein X₀ is the initial vector and Y₀ is zero, Δτ is the size of the time step, ν and w are mutually independent Brownian motion with ν,w˜N(0,1). The algorithm of “States and Observation Generator” is stated as the following Algorithm 1.

| Input: a terminal time Γ, time step Δτ, the initial state X₀, the | |
|---|---|
| vector-valued functions f, h | |
| Output: the state X(t) and observation Y(t) at t = τ₀, . . . , τ_{N}, | |
| 1. | ${N}_{τ} = \frac{Γ}{Δτ} + 1.$ |
| 2. | Set the initial state X(τ₀) = X₀. |
| 3. | Generate v,w ~ N(0,1), v ⊥ w. |
| 4. | for k = 1 to N_{τ} do |
| 5. | X(τₖ) = X(τₖ₋₁) + f(X(τₖ₋₁))Δτ + v\sqrt{Δτ}. |
| 6. | end for |
| 7. | Y(τ₀) = 0. |
| 8. | for k = 1 to N_{τ} do |
| 9. | Y(τₖ) = X(τₖ₋₁) + h(X(τₖ₋₁))Δτ + w\sqrt{Δτ.} |
| 10. | end for |

The IEM is proposed for solving the Kolmogorov equations (2). From the equation (5), the state vector X(t) can be estimated by the solution of the equation (2). For each time interval, [τₖ₋₁, τₖ], k=1, . . . , Nᵣ, is partitioned uniformly by

P_{[r}_{_{k−1}}_{, r}_{ₜ}_{]}={τₖ₋₁=t₀^{(k)}<t₁^{(k)}<. . . <t_{N},^{(k)}=τₖ},

wherein tₙ^{(k)-t}ₙ₋₁^{(k)=Δt, n=}1, . . . , Nᵣ. Then the partition

$${P}_{[ 0 , Γ ]}^{*} = {{⋃}_{k = 1}}^{{N}_{τ}} {P}_{[ {τ}_{k - 1} , {τ}_{k} ]} = \{ 0 = {τ}_{0} = {t}_{0}^{( 1 )} < … < {t}_{{N}_{t}}^{( 1 )} = {τ}_{1} = {t}_{0}^{( 2 )} < … < {t}_{{N}_{t}}^{( 2 )} = {τ}_{2} = {t}_{0}^{( 3 )} < … < {t}_{{N}_{t}}^{( {N}_{τ} )} = {τ}_{{N}_{τ}} = Γ \}$$

forms a refinement of the partition P_{[0, r]} in (6). On the other hand, the space interval [−R, R] can be uniformly discretized by

P_{[-R,R]}={−R=s₀<s₂<. . . <s_{N}, =R},

wherein sⱼ−sⱼ₋₁=Δs, j=1, 2, . . . , Nₛ and R is a suitably large number so that the Gaussian distribution can be ignored outside [−R,R]. For the discretization of a D-cell [−R,R]^{D} ⊂ R^{D}, an ordered set of the power set of P_{[-R,R]}, is considered.

P_{[-R,R]}^{D}={sⱼ}ⱼ₌₁^{(N}^{ₛ}⁾^{^{D}},

wherein sⱼ=(sⱼ⁽¹⁾, sⱼ⁽²⁾, . . . , sⱼ^{(D)})^{T}, sⱼ^{(d)} ∈ P_{[-R,R], j=}1, . . . , (Nₛ)^{D}, d=1, . . . , D. For the d-th dimension of the space, d=1, . . . , D, the second order partial differential operator can be approximated by using the Euler central difference scheme

$$\frac{{\partial }^{2} \tilde{u}}{\partial {s}^{2}} ( {t}_{n} , {s}_{j} ) \approx [ α ( \frac{{U}_{j + 1}^{n + 1} - 2 {U}_{j}^{n + 1} + {U}_{j - 1}^{n + 1}}{{( Δ s )}^{2}} ) + β ( \frac{{U}_{j + 1}^{n} - 2 {U}_{j}^{n} + {U}_{j - 1}^{n}}{{( Δ s )}^{2}} ) ] , \qquad ( 7 )$$

wherein Uⱼⁿ≡ũ(tₙ,sⱼ) and α+β=1, α,β≧0. Similarly, the partial differential operator can be approximated by

$$\frac{{\partial }^{2} \tilde{u}}{\partial s} ( {t}_{n} , {s}_{j} ) \approx [ α ( \frac{{U}_{j + 1}^{n + 1} - {U}_{j - 1}^{n + 1}}{2 Δ s} ) + β ( \frac{{U}_{j + 1}^{n} - {U}_{j - 1}^{n}}{2 Δ s} ) ] . \qquad ( 8 )$$

In other words, the discretized Laplacian operator in (2) can be represented by the matrix

$${T}_{d} ≡ [ ( {{⊗}^{D - d}}_{k = 1} {I}_{{N}_{s}} ) ⊗ {T}_{d} ⊗ ( {{⊗}_{k = D - d + 2}}^{D} {{I}_{N}}_{s} ) ] , \qquad ( 9 )$$

wherein [symbol] denotes the Kronecker product (or tensor product), I_{N}_{ₛ} is the identity matrix of size Nₛ and the matrix

$${T}_{d} = \frac{1}{{( Δ s )}^{2}} [ \begin{matrix}- 2 & 1 & & & \\ 1 & - 2 & 1 & & \\ & 1 & - 2 & ⋱ & \\ & & ⋱ & ⋱ & 1 \\ & & & 1 & - 2\end{matrix} ] .$$

Similarly, the discretized partial differential operator can be represented by the matrix

$${K}_{d} ≡ [ ( {{⊗}^{D - d}}_{k = 1} {{I}_{N}}_{s} ) ⊗ {K}_{d} ⊗ ( {{⊗}_{k = D - d + 2}}^{D} {{I}_{N}}_{s} ) ] , \qquad ( 10 )$$

wherein the matrix

$${K}_{d} = \frac{1}{2 Δ s} [ \begin{matrix}0 & 1 & & & \\ - 1 & 0 & 1 & & \\ & - 1 & 0 & ⋱ & \\ & & ⋱ & ⋱ & 1 \\ & & & - 1 & 0\end{matrix} ] .$$

For each time period tₙ^{(k)} ∈[τₖ₋₁, τₖ], the partial differential of time

$$\frac{\partial {\tilde{u}}_{k}}{\partial t} ( {t}_{n} , s )$$

in (2) can be discretized by

$$\frac{\partial {\tilde{u}}_{k}}{\partial t} ( {t}_{n} , s ) \approx \frac{{U}^{( k ) , n + 1} - {U}^{( k ) , n}}{Δ t} , \qquad ( 11 )$$

wherein U^{(k),n}≡(ũₖ(tₙ,s₁),ũₖ(tₙ, s₂), . . . , ũₖ(tₙ, s_{(N}_{ₛ}₎_{^{D}}))^{T}. Hence the numerical scheme can be written in the form

$$\frac{{U}^{( k ) , n} - {U}^{( k ) , n - 1}}{Δ t} = α {AU}^{( k ) , n} + β {AU}^{( k ) , n - 1} , \qquad ( 12 )$$

wherein α+β=1, α, β≧0 and the matrix

$$A = \frac{1}{2} {\sum }_{d = 1}^{D} {T}_{d} + {\sum }_{d = 1}^{D} {P}_{d} {K}_{d} + Q , \qquad ( 13 )$$

P_{d}≡diag{p_{d}(s₁)}ⱼ₌₁^{(N}^{ₛ}⁾^{^{D}}, Q≡diag {q(s₁)}ⱼ₌₁^{(N}^{ₛ}⁾^{^{D}} are diagonal matrices. For each tₙ^{(k) ∈[τ}ₖ₋₁, τₖ], j=1, . . . , Nₜ, the linear system is solved

[l−α(Δt) A]U^{(k)n}=[I+β(Δt)A]U^{(k)n-1}, (14)

for k=1, . . . , Nᵣ with the initial vector U^{(k), 0}≡(U₁^{(k),0}, U₂^{(k),0}, . . . , U_{(N}_{ₛ}₎_{^{D}}^{(k),0})^{T}, in which

$${U}_{j}^{( k ) , 0} = exp \{ {\sum }_{d = 1}^{M} [ y ( {τ}_{k + 1} ) - y ( {τ}_{k} ) {h}_{d} ( {s}_{j} ) ] \} {U}^{( k - 1 ) , N ,} , \\ j = 1 , … , {( {N}_{s} )}^{D} . \qquad ( 15 )$$

Each vector U^{(k),n} in (14) should be normalized such that Σⱼ₌₁^{(N}^{_{d}}⁾^{^{b}}Uⱼ^{(k),n}=1.
Then the vector U^{(k),n} represents the probability distribution of the state at time tₙ^{(k)}. Finally, the expectation is computed

$$\hat{X} ( {t}_{n}^{( k )} ) = {\sum }_{j = 1}^{{( {N}_{d} )}^{D}} {s}_{j} {U}_{j}^{( k ) , n} \qquad ( 16 )$$

as the estimation for the real state X(tₙ^{(k)}). In particular, the parameter α=1 and β=0 is chosen since the implicit scheme is stable in most of case while the explicit scheme (α=1, β=1) is usually unstable. The algorithm of “IEM for Nonlinear Filter” for solving the nonlinear filtering problem is stated as the following Algorithm 2.

Input: a terminal time Γ, the space interval [−R, R]^{D}, the time
step size Δt, the space step size Δs, the vector-valued functions
f = (f₁, . . . , f_{D})^{T}, h = (h₁, . . . , h_{M})^{T}, the observations {Yₖ}ₖ₌₁^{N}^{ₜ} and the
initial state σ₀
Output: the approximation of the state \hat{X}(t)

| | |
|---|---|
| 1. | $Set the values {N}_{τ} = \frac{Γ}{Δτ} + 1 , {N}_{t} = \frac{Δτ}{Δt} + 1 and {N}_{s} = \frac{2 R}{Δs} + 1.$ |
| 2. | for j = 1 to (Nₛ)^{D} do |
| 3. | Uⱼ ← σ₀(sⱼ)exp{Σ_{d=1}^{M}y_{d}(τ₀)h_{d}(sⱼ)}. |
| 4. | end for |
| 5. | for k = 1 to Nₜ do |
| 6. | for j = 1 to (Nₛ)^{D} do |
| 7. | Uⱼ ← σ₀(sⱼ)exp{Σ_{d=1}^{M}[y_{d}(τₖ₊₁) − y_{d}(τₖ)]h_{d}(sⱼ)}Uⱼ as in (15) |
| 8. | end for |
| 9. | for n = 1 to Nₜ do |
| 10. | Uₜₘₚ = [I + β(Δt)A]U. |
| 11. | Solve the linear system [I = β(Δt)A]U = Uₜₘₚ as in (14) |
| 12. | $Normalize the solution U ← \frac{U}{{Σ}_{j = 1}^{{( {N}_{s} )}^{D}} {U}_{j}} .$ |
| 13. | Set the approximation of state \hat{X}(tₙ^{(k)}) = Σⱼ₌₁^{(Ns)}^{_{D}}sⱼUⱼ as in (16) |
| 14. | end for |
| 15. | end for |

The FFTs for the discretized Laplacian matrix Δ is well-known. In the equations (12) and (13), the quasi-implicit scheme is considered as

$$( 1 - \frac{Δ t}{2} Δ ) {U}^{( k ) , n} = [ I + Δ t ( {\sum }_{d = 1}^{D} {P}_{d} {K}_{d} + Q ) ] {U}^{( k ) , n - 1} , \qquad ( 17 )$$

wherein Δ≡Σ_{d=1}^{D} T_{d}, then the linear system (17) can be efficiently solve by FFTs. For the case of D=1 (one-dimensional case), the Laplacian matrix in (17) satisfies Δ₁≡T₁. By the Fourier sine transformation, the spectral decomposition is:

$${T}_{1} = \frac{1}{{( Δ s )}^{2}} {WSW}^{*} ,$$

wherein W≡└Wᵢⱼ┘ with Wᵢⱼ=sin (ijπΔs), and

$$s ≡ diag {\{ - 4 {sin}^{2} ( \frac{i πΔ s}{2} ) \}}_{i = 1}^{{N}_{s}} .$$

Then the linear system of Δ₁ can be solved by calling the MATLAB function “FFT”. the algorithm of “QIEM for Nonlinear Filter with FFTs” for solving the D-dimensional nonlinear filtering problem by applying the FFT is stated as the following Algorithm 3.

Input: a terminal time Γ, the space interval [−R, R]^{D}, the time
step size Δt, the space step size Δs, the vector-valued functions
f = (f₁, . . . , f_{D})^{T}, h = h₁, . . . , h_{M})^{T}, the observations {Yₖ}ₖ₌₁^{N}^{ₛ} and the
initial state σ₀
Output: the approximation of the state \hat{X}(t)

| | |
|---|---|
| 1. | $Set the value {N}_{τ} = \frac{Γ}{Δτ} + 1 , {N}_{t} = \frac{Δτ}{Δt} + 1 and {N}_{s} = \frac{2 R}{Δs} + 1.$ |
| 2. | for j = 1 to (Nₛ)^{D} do |
| 3. | Uⱼ ← σ₀(sⱼ)exp{Σ_{d=1}^{M}y_{d}(τ₀)h_{d}(sⱼ)}. |
| 4. | end for |
| 5. | for k = 1 to N_{τ} do |
| 6. | for j = 1 to (Nₛ)^{D} do |
| 7. | Uⱼ ← σ₀(sⱼ)exp{Σ_{d=1}^{M}[y_{d}(τₖ₊₁) − y_{d}(τₖ)h_{d}(sⱼ)}Uⱼ as in (15) |
| 8. | end for |
| 9. | for n = 1 to Nₜ do |
| 10. | Uₜₘₚ ← └I + Δt(Σ_{d=1}^{D}P_{d}K_{d} + Q)┘U. |
| 11. | Call FFTs: U ← ( [symbol] _{d=1}^{D}W*)Utmp. |
| 12. | for j = 1 to Nₛ do |
| 13. | ${U}_{j} ← {U}_{j} / [ 1 + \frac{2 Δt}{{( Δs )}^{2}} {sin}^{2} ( \frac{j πΔs}{2} ) ] .$ |
| 14. | end for |
| 15. | Call IFFTs: U ← ( [symbol] _{d=1}^{D}W*)U |
| 16. | $Normalize the solution U ← \frac{U}{{Σ}_{j = 1}^{{( {N}_{s} )}^{D}} {U}_{j}} .$ |
| 17. | Set the approximation of state \hat{X}(tₙ^{(k)} = Σⱼ₌₁^{(N}^{ₛ}⁾^{^{D}}sⱼUⱼ as in (16) |
| 18. | end for |
| 19. | end for |

The Laplacian matrix in (17) is a second-order approximation of the Laplacian operator. Hereafter, a fourth-order accurate scheme for Laplacian operator which reduces the size of the discretization matrix considerably is considered, but preserves the same accuracy as the second-order approximation. Since there is no general form of the higher-order scheme for Laplacian operator, for convenience in practice, the Kolmogorov equations (2) in two-dimensional case is considered.

The 9-point scheme for the discretized Laplacian operator \tilde{Δ}₂ is defined by:

$${\tilde{Δ}}_{2} {U}_{i , j} = \frac{1}{6 {( Δ s )}^{2}} [ 4 {U}_{i - 1 , j} + 4 {U}_{i + 1 , j} + 4 {U}_{i , j - 1} + 4 {U}_{i , j + 1} + {U}_{i - 1 , j - 1} + {U}_{i + 1 , j - 1} + {U}_{i - 1 , j + 1} + {U}_{i + 1 , j + 1} - 20 {U}_{i , j} ] \qquad ( 19 )$$

which is a fourth-order approximation of Laplacian operator.
The matrix form of (19) is represented as

$${\tilde{Δ}}_{2} = \frac{1}{{( Δ s )}^{2}} [ \begin{matrix}Σ & Φ & & \\ Φ & Σ & ⋱ & \\ & ⋱ & ⋱ & Φ \\ & & Φ & Σ\end{matrix} ] , wherein \\ Σ = \frac{1}{3} [ \begin{matrix}- 10 & 2 & & \\ 2 & - 10 & ⋱ & \\ & ⋱ & ⋱ & 2 \\ & & 2 & - 10\end{matrix} ] , Φ = \frac{1}{6} [ \begin{matrix}4 & 1 & & \\ 1 & 4 & ⋱ & \\ & ⋱ & ⋱ & 1 \\ & & 1 & 4\end{matrix} ] . \qquad ( 20 )$$

Since the matrix \tilde{Δ}₂ is also a Toeplitz matrix, the fast Fourier transformation is derived for solving the linear system \tilde{Δ}₂U=b. Note that

$$\begin{matrix}{\tilde{Δ}}_{2} = ( \frac{1}{6} [ ( {T}_{1} + 6 I ) ⊗ ( {T}_{1} + 6 I ) ] - 6 I ) \\ = \frac{1}{6 {( Δ s )}^{2}} ( [ ( {WSW}^{*} + 6 I ) ⊗ ( {WSW}^{*} + 6 I ) ] - 36 I ) \\ = \frac{1}{6 {( Δ s )}^{2}} ( ( W ⊗ W ) ( ( S + 6 I ) {W}^{*} ⊗ ( S + 6 I ) {W}^{*} ) - 36 I ) \\ = \frac{1}{6 {( Δ s )}^{2}} ( ( W ⊗ W ) ( ( ( S + 6 I ) ⊗ ( S + 6 I ) ) - 36 ( I ⊗ I ) ) ( {W}^{*} ⊗ {W}^{*} ) )\end{matrix}$$

wherein

$${T}_{1} = \frac{1}{{( Δ s )}^{2}} {WSW}^{*}$$

as given in (18). Based on the QIEM Algorithm 3, the algorithm “Fourth-order QIEM for 2-D Nonlinear Filter with FFTs” for solving the two-dimensional nonlinear filtering problem by applying the fourth-order QIEM with FFTs is stated in the following Algorithm 4.

Input: a terminal time Γ, the space interval [−R, R], the time step
size Δt, the space step size Δs, the functions f = (f₁, f₂)^{T},
h = (h₁, h₂)^{T}, the observations {Y(τₖ) = (y₁(τₖ), y₂(τₖ))^{T}}ₖ₌₁^{N}^{ₛ} and the
initial state σ₀
Output: the approximation of the state \hat{X}(t)

| | |
|---|---|
| 1. | $Set the values {N}_{τ} = \frac{Γ}{Δτ} + 1 , {N}_{t} = \frac{Δτ}{Δt} + 1 and {N}_{s} = \frac{2 R}{Δs} + 1.$ |
| 2. | for j = 1 to (Nₛ)² do |
| 3. | Uⱼ ← σ₀(sⱼ)exp{y₁(τ₀)h₁(sⱼ) + y₂(τ₀)h₂(sⱼ)}. |
| 4. | end for |
| 5. | for k = 1 to N_{τ} do |
| 6. | for j = 1 to Nₛ do |
| 7. | Uⱼ ← exp{[y₁(τₖ₊₁) − y₁(τₖ)]h₁(sⱼ) + [y₂τₖ₊₁) − y₂(τₖ)]h₂(sⱼ)}Uⱼ |
| 8. | end for |
| 9. | for n = 1 to Nₜ do |
| 10. | Uᵢₘₚ ← [I + Δt(P₁D₁ + P₂D₂ + Q)]U. |
| 11. | % Here the matrixes W and S are defined in (18). |
| 12. | Call FFTs: U ← (W* [symbol] W*)Uᵢₘₚ. |
| 13. | for j = 1 to Nₛ do |
| 14. | ${U}_{j} ← {[ ( I ⊗ I ) - \frac{Δt}{12 {( Δs )}^{2}} ( ( S + 6 I ) ⊗ ( S + 6 I ) - 36 ( I ⊗ I ) ) ]}^{- 1} {U}_{j} .$ |
| 15. | end for |
| 16. | Call FFTs: U ← (W [symbol] W)U. |
| 17. | $Normalize the solution U ← \frac{U}{{Σ}_{j = 1}^{{N}_{s}} {U}_{j}} .$ |
| 18. | Set the approximation of state \hat{X}(tₙ^{(k)}) = Σⱼ₌₁^{(N}^{ₛ}⁾^{²}sⱼUⱼ |
| 19. | end for |
| 20. | end for |

The computation of nonlinear filtering problem is a real time problem. Saving the computational cost becomes an essential issue. In order to solve the nonlinear filtering problem in a more efficient way, the superposition technique is adopted, and the Dirac delta functions is

{δ_{C}_{ᵢ}(S)=e^{-η|s-C}^{ₖ}^{|}^{¹}|Cₖ=(cₖ_{ₗ}, . . . , cₖ_{_{D}})^{τ} ∈[−R, R]^{D}}ₖ₌ᵢ^{N}^{ₛ}

with S=(sᵢ, . . . , s_{D})^{τ} ∈R^{D} and ∥S−Cₖ∥²=Σⱼ₌₁^{D}(sⱼ−cₖ_{ⱼ})², as various initials to compute the approximate states for the nonlinear filtering problem, separately. Then all the fundamental solutions {νₖ}ₖ₌₁^{N}^{ₛ} corresponding to the Dirac delta functions {δ_{c}_{ₖ}}ₖ₌₁^{N}^{_{D}} are stored.

In practice, for any given initial probability density function u₀, a set of coefficients {αₖ}ₖ₌₁^{N}^{ₛ} of the linear combination of Dirac delta functions is calculated to satisfy

$${u}_{0} \approx {\sum }_{k = 1}^{{N}_{s}} {α}_{k} {δ}_{{C}_{k}} .$$

Then the approximate probability density function of the state v can be directly obtained by computing the linear combination of the fundamental solutions

$$v \approx {\sum }_{k = 1}^{{N}_{s}} {α}_{k} {v}_{k} .$$

This method significantly saves a large amount of computational cost.

The linear operator defined in (14) is a nonnegative operator, the solution of each time step represents a probability distribution of the space. In order to guarantee the property that each solution is nonnegative, it is found that the sufficient condition such that the matrix (I−ΔtA)⁻¹ is a nonnegative operator. First, the definition of an M-matrix and its equivalence condition are as follows.

Definition: A real matrix B=└Bᵢⱼ┘ is called an M-matrix if Bᵢⱼ≦0, i≠j and B⁻¹ exists with B⁻¹≧0.
Lemma : (Equivalence Condition of M-matrix). Let B be a real matrix with Bᵢⱼ≦0 for i≠j. Then B is an M-matrix if and only if there is a positive vector ν>0 such that B_{ν}>0.
The following thereon shows that the vector U in each iteration of step 11 in Algorithm 2 preserves nonnegativity of the probability density function.
Theorem 1: (Sufficient Condition of Nonnegative Operator). Given real-valued functions p_{d}, d=1, . . . , D, q, a time step Δt and a space step Δs. Let B≡I−ΔtA, wherein A (13). If for each s ∈[−R, R]^{D},

$$\vert {p}_{d} ( S ) \vert < \frac{1}{Δ s} , \vert q ( S ) \vert < \frac{1}{Δ t} , \qquad ( 21 )$$

for d=1, . . . , D, the B is an M-matrix. That is, B⁻¹≧0 is a nonnegative operator.
Proof. First to check Bᵢⱼ≦0 for i≠j. From the structure of the matrices in (9) and (10) that for i≠j either Bᵢⱼ=0 or

$$\begin{matrix}{B}_{ij} = - Δ t ( \frac{1}{2 {( Δ s )}^{2}} + \frac{{p}_{d} ( S )}{2 Δ s} ) \\ = - \frac{Δ t}{2 {( Δ s )}^{2}} ( 1 + Δ {sp}_{d} ( S ) ) \\ \leq - \frac{Δ t}{2 {( Δ s )}^{2}} ( 1 - Δ s \vert {p}_{d} ( S ) \vert ) \\ < 0\end{matrix} \qquad ( 22 )$$

Then inequality (22) follows from the first equation of (21). Next, B1>0 is checked, wherein 1≡(1, 1, . . . , 1)^{τ}>0. Note that B1 is a vector whose entry is the row sum of B. Hence

$$\begin{matrix}B 1 = 1 - Δ t ( \frac{- k}{2 {( Δ s )}^{2}} + \frac{{{Σ}_{d = 1}^{k} ( - 1 )}^{{m}_{d}} {p}_{d} ( S )}{2 Δ s} + q ( S ) ) \\ \geq 1 - Δ t ( \frac{- k}{2 {( Δ s )}^{2}} + \frac{{kmax}_{d} \vert {p}_{d} ( S ) \vert}{2 Δ s} + q ( S ) ) \\ = ( 1 - Δ tq ( S ) ) + \frac{k Δ t}{2 {( Δ s )}^{2}} ( 1 - Δ s {max}_{d} \vert {p}_{d} ( S ) \vert ) \\ \geq ( 1 - Δ t \vert q ( S ) \vert ) + \frac{k Δ t}{2 {( Δ s )}^{2}} ( 1 - Δ s {max}_{d} \vert {p}_{d} ( S ) \vert ) \\ > 0 ,\end{matrix} \qquad ( 23 )$$

for some k ∈{1, . . . , D}, m_{d} ∈{0, 1}. The inequality (23) follows from (21). By Lemma 1, B is an M-matrix. That is, B⁻¹≧0.
Consequently, by Theorem 1, the vector U=[I−ΔtA]⁻¹Uₜₘₚ in Step 11 of Algorithm 2 is nonnegative.

The convergence of the IEM and the QIEM is proved by checking the consistency and the stability of the schemes.

Theorem 2: (Consistency of IEM.QIEM). The local truncation errors of IEM (12) and QIEM (17) are O(Δt+(Δs)²). That is, IEM and QIEM are consistent.
Proof. The first-order Taylor expansion of u at the point (t+Δt,s) implies

$$\frac{\partial u}{\partial t} ( t , s ) = \frac{u ( t + Δ t , s ) - u ( t , s )}{Δ t} + O ( Δ t ) . \qquad ( 24 )$$

The third-order Taylor expansions of u at the points (t,s+Δs) and (t,s−Δs), respectively, lead to

$$\begin{matrix}u ( t , s + Δ s ) = u ( t , s ) + Δ s \frac{\partial u}{\partial s} ( t , s ) + \frac{{( Δ s )}^{2}}{2} \frac{{\partial }^{2} u}{\partial {s}^{2}} ( t , s ) + \frac{{( Δ s )}^{3}}{6} \frac{{\partial }^{3} u}{\partial {s}^{3}} ( t , s ) + O ( {( Δ s )}^{4} ) & ( 25 ) \\ and & \\ u ( t , s - Δ s ) = u ( t , s ) + Δ s \frac{\partial u}{\partial s} ( t , s ) + \frac{{( Δ s )}^{2}}{2} \frac{{\partial }^{2} u}{\partial {s}^{2}} ( t , s ) - \frac{{( Δ s )}^{3}}{6} \frac{{\partial }^{3} u}{\partial {s}^{3}} ( t , s ) + O ( {( Δ s )}^{4} ) . & ( 26 )\end{matrix}$$

By adding the equations (25) and (26), obtaining

$$\frac{{\partial }^{2} u}{\partial {s}^{2}} ( t , s ) = \frac{u ( t , s + Δ s ) - 2 u ( t , s ) + u ( t , s - Δ s )}{{( Δ s )}^{2}} + O ( {( Δ s )}^{2} ) . \qquad ( 27 )$$

Similarly, by subtracting the equation (26) rom (25), obtaining

$$\frac{\partial u}{\partial s} ( t , s ) = \frac{u ( t , s + Δ s ) - u ( t , s - Δ s )}{2 Δ} + O ( {( Δ s )}^{2} ) . \qquad ( 28 )$$

Hence, according to the equations (7), (8) and (11), respectively, the equations (27), (28) and (24) show the local truncation error of (12) is O(Δt+(Δs)²).
Theorem 3: (Sufficient Condition for Stability of IEM). The IEM (12) is stable if the function f in (1) satisfies

∇·ƒ≧0. (29)

Proof. IEM (12) is stable by applying von Neumann stability analysis. Let Uⱼⁿ=ξ(k)ⁿe^{tkj(Δs)}, wherein t≡\sqrt{−1} and ξ(k) is known as the amplification factor. Substituting Uⱼⁿ into the scheme (12), obtaining

$$\frac{ξ ( k ) - 1}{Δ t} = \frac{ξ ( k )}{2 {( Δ s )}^{2}} ( {e}^{ikj ( Δ s )} - 2 + {e}^{- ikj ( Δ s )} ) + \frac{ξ ( k )}{2 Δ s} ( {e}^{ikj ( Δ s )} - {e}^{ikj ( Δ s )} ) p ( x ) + ξ ( k ) q ( s )$$

### That is,

$$\begin{matrix}ξ ( k ) = {[ 1 - Δ t ( \frac{{e}^{ikj ( Δ s )} - 2 + {e}^{ikj ( Δ s )}}{2 {( Δ s )}^{2}} + \frac{{e}^{ikj ( Δ s )} - {e}^{ikj ( Δ s )}}{2 Δ s} p ( s ) + q ( s ) ) ]}^{- 1} \\ = {[ 1 - \frac{Δ t}{{( Δ s )}^{2}} ( cos ( kj ( Δ s ) ) - 1 + i sin ( kj ( Δ s ) ) p ( s ) Δ s + q ( s ) {( Δ s )}^{2} ) ]}^{- 1} \\ = {[ \begin{matrix}1 + \frac{Δ t}{{( Δ s )}^{2}} ( 1 - cos ( kj ( Δ s ) ) - q ( s ) {( Δ s )}^{2} ) - \\ \frac{Δ t}{{( Δ s )}^{2}} i sin ( kj ( Δ s ) ) p ( s ) Δ s\end{matrix} ]}^{- 1} \\ = \frac{1 + \frac{Δ t}{{( Δ s )}^{2}} ( 1 - cos ( kj ( Δ s ) ) - q ( s ) {( Δ s )}^{2} ) + \frac{Δ t}{{( Δ s )}^{2}} i sin ( kj ( Δ s ) ) p ( s ) Δ s}{\begin{matrix}{( 1 + \frac{Δ t}{{( Δ s )}^{2}} ( 1 - cos ( kj ( Δ s ) ) - q ( s ) {( Δ s )}^{2} ) )}^{2} + \\ {( \frac{Δ t}{{( Δ s )}^{2}} i sin ( kj ( Δ s ) ) p ( s ) Δ s )}^{2}\end{matrix}} .\end{matrix}$$

If ∇·ƒ≧0, then

$$q ( s ) ≡ - [ ∇ \cdot f + \frac{1}{2} {\sum }_{j = 1}^{M} {h}_{j}^{2} ( S ) ] \leq 0.$$

It follows that

$$\begin{matrix}{\vert ξ ( k ) \vert}^{2} = \frac{\begin{matrix}{( 1 + \frac{Δ t}{{( Δ s )}^{2}} ( 1 - cos ( kj ( Δ s ) ) - q ( s ) {( Δ s )}^{2} ) )}^{2} + \\ {( \frac{Δ t}{{( Δ s )}^{2}} i sin ( kj ( Δ s ) ) p ( s ) Δ s )}^{2}\end{matrix}}{{( \begin{matrix}{( 1 + \frac{Δ t}{{( Δ s )}^{2}} ( 1 - cos ( kj ( Δ s ) ) - q ( s ) {( Δ s )}^{2} ) )}^{2} + \\ {( \frac{Δ t}{{( Δ s )}^{2}} i sin ( kj ( Δ s ) ) p ( s ) Δ s )}^{2}\end{matrix} )}^{2}} \\ = {[ \begin{matrix}{( 1 + \frac{Δ t}{{( Δ s )}^{2}} ( 1 - cos ( kj ( Δ s ) ) - q ( s ) {( Δ s )}^{2} ) )}^{2} + \\ {( \frac{Δ t}{Δ s} i sin ( kj ( Δ s ) ) p ( s ) )}^{2}\end{matrix} ]}^{- 1} \\ \leq {[ {( 1 - Δ tq ( s ) )}^{2} ]}^{- 1} \leq 1\end{matrix}$$

This implies that IEM (12) is stable under the assumption that ∇∫ƒ≧0. Theorem 4: (Sufficient Condition for Stability of OIEM). The QIEM (17) is stable if both the step size of time Δt and the step size of space Δs are sufficient small. More precisely, ≢t and Δs satisfy

(Δs)²(2q(s)+q(s)²Δt)+Δtp(s)²≦2. (30)

Proof. As in the proof of Theorem 3, Uⱼ^{N}=ξ(k)ⁿ e^{tkj(Δt)} is substituted into the scheme (17) to obtain

$$\frac{ξ ( k ) - 1}{Δ t} = \frac{ξ ( k )}{2 {( Δ s )}^{2}} ( {e}^{ikj ( Δ s )} - 2 + {e}^{ikj ( Δ s )} ) + \frac{1}{2 Δ s } ( {e}^{ikj ( Δ s )} - {e}^{ikj ( Δ s )} ) p ( s ) + q ( s ) .$$

### That is,

$$ξ ( k ) = \frac{1 + Δ tq ( s ) + \frac{Δ t}{Δ s} i sin ( kj ( Δ s ) ) p ( s )}{1 - \frac{Δ t}{{( Δ s )}^{2}} ( cos ( kj ( Δ s ) ) - 1} .$$

If Δs and Δt satisfy (Δs)²(2q(s)²Δt)+Δtp(s)²≦2, then

$${( Δ s )}^{2} ( 2 q ( s ) + {q ( s )}^{2} Δ t ) + Δ {tp ( s )}^{2} \leq 2 + \frac{Δ t }{{( Δ s )}^{2}} .$$

Multiplying both side by

$$\frac{Δ t}{{( Δ s )}^{2}} ,$$

having

$$2 q ( s ) Δ t + {q ( s )}^{2} {( Δ t )}^{2} + \frac{{( Δ t )}^{2}}{{( Δ s )}^{2}} {p ( s )}^{2} \leq \frac{2 Δ t}{{( Δ s )}^{2}} + \frac{{( Δ t )}^{2}}{{( Δ s )}^{4}} .$$

Adding both side by 1, obtaining

$${( 1 + Δ tq ( s ) )}^{2} + {( \frac{Δ t}{Δ s} p ( s ) )}^{2} \leq {( 1 + \frac{Δ t}{( Δ s )} )}^{2} .$$

It follows that

$${\vert ξ ( k ) \vert}^{2} = \frac{{( 1 + Δ tq ( s ) )}^{2} {( \frac{Δ t}{Δ s} sin ( kj ( Δ s ) ) p ( s ) )}^{2}}{{( 1 - \frac{Δ t}{{( Δ s )}^{2}} ( cos ( kj ( Δ s ) ) - 1 ) )}^{2}} \leq \frac{{( 1 + Δ tq ( s ) )}^{2} + {( \frac{Δ t}{Δ s} p ( s ) )}^{2}}{{( 1 + \frac{Δ t}{{( Δ s )}^{2}} )}^{2}} \leq 1$$

This implies QIEM (17) is stable under the given assumption. Theorem 5: (Sufficient Conditions for Convergence of IEM/QIEM). The IEM and QIEM converge if the conditions of (29) and (30) hold, respectively.
Proof. From the consistency of IEM/QIEM in Theorem 2 as well as the stabilities of IEM and QIEM in Theorem 3 and Theorem 4, respectively, the convergence if IEM/QIEM follows by the Lax-Richtmyer equivalence theorem immediately.

In summary, the method for solving high-dimensional nonlinear filtering problems of the preset invention has the following advantages compared with algorithms and schemes available now.

1. The method of the present invention solves D-dimensional nonlinear filtering problems and gets approximate numerical solutions based on Yau-Yau filtering theory. The Quasi-Implicit Euler Method (QIEM) is applied to solve the Kolmogorov equations and estimate approximate numerical solutions of the signal-observation model. Moreover, QIEM is feasible for acceleration by fast Fourier transformation (FFT). Thus stability of the numerical solutions is ensured and a large amount of computational cost is saved.

2. The method of the present invention guarantees nonnegativity of the numerical solutions of Kolmogorov equations in each iteration and preserves probability density functions in the iterative process. The numerical results show that the method is efficient and promising.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed its:

1. A method for solving high-dimensional nonlinear filtering problems comprising the steps of:
solving an equation by a fast computational module to obtain approximate numerical solutions of a signal-observation model; and
accelerating a process of solving the equation by the fast computational module for improving computational stability.

2. The method claimed in claim 1, wherein a Quasi-Implicit Euler Method(QIEM) is applied to solve Kolmogorov equations and obtain the approximate numerical solutions of the signal-observation model.

3. The method as claimed in claim 2, wherein the Quasi-Implicit Euler Method (QIEM) is iteratively formulated by:
$$[ {I}_{{N}^{D}} - \frac{Δ t}{2 {( Δ s )}^{2}} {L}_{N}^{( D )} ] {u}_{n + 1} = [ {I}_{{N}^{D}} + Δ t ( \frac{1}{2 Δ s} {K}_{ N}^{( D )} + {Q}_{N}^{( D )} ) ] {u}_{N} ;$$
wherein
$${L}_{N}^{( D )} = {\sum }_{d = 1}^{D} [ {I}_{{N}^{D - d}} ⊗ {L}_{N} ⊗ {I}_{{N}^{d - 1}} ] , \\ {K}_{N}^{( D )} = {\sum }_{d = 1}^{D} {P}_{d} [ {I}_{{N}^{D - d}} ⊗ {K}_{N} ⊗ {I}_{{N}^{d - 1}} ] ;$$
wherein I_{N} is the identity matrix of size N and P_{d}=diag{p_{d}(s₁)}ⱼ₌₁^{N}^{^{D}}, Q=diag{q(s₁)}ⱼ₌₁^{N}^{^{D}};
wherein the matrices L_{N} and K_{N} are defined by
$${L}_{N} = [ \begin{matrix}- 2 & 1 & & \\ 1 & - 2 & … & \\ & … & … & 1 \\ & & 1 & - 2\end{matrix} ] , \\ {K}_{N} = [ \begin{matrix}0 & 1 & & \\ - 1 & 0 & … & \\ & … & … & 1 \\ & & - 1 & 0\end{matrix} ] .$$
